(19) United States
(12) Patent Application Publication
(10) Pub. No.: US 2016/0351495 A1
(43) Pub. Date: Dec. 1, 2016

(54) PROCESS FOR MANUFACTURING INTEGRATED ELECTRONIC DEVICES, IN PARTICULAR CMOS DEVICES USING A BORDERLESS CONTACT TECHNIQUE

(71) Applicant: STMICROELECTRONICS S.R.L., Agrate Brianza (IT)

(72) Inventors: Sara PAOLILLO, Milano (IT); Giovanni TAGLIABUE, Monza (IT); Simone Dario MARIANI, Vedano al Lambro (IT)

(21) Appl. No.: 14/966,435

(22) Filed: Dec. 11, 2015

(30) Foreign Application Priority Data
May 29, 2015 (IT) 102015000019455

(51) Int. Cl. H01L 23/522; H01L 27/092; H01L 21/8238; H01L 21/768; H01L 23/532

(52) U.S. Cl. CPC H01L 23/5226; H01L 21/76802; H01L 21/76877; H01L 21/76819; H01L 23/53295; H01L 21/823871; H01L 27/092

(57) ABSTRACT

For manufacturing an integrated electronic device, a protection layer, of a first material, is formed over a body having a non-planar surface; a first dielectric layer, of a second material, is formed over the protection layer, the second material being selectively etchable with respect to the first material; an intermediate layer, of a third material, is formed over the first dielectric layer, the third material being selectively etchable with respect to the second material; a second dielectric layer, of a fourth material, is formed over the intermediate layer, the fourth material being selectively etchable with respect to the third material; vias are formed through the second dielectric layer, the intermediate layer, the first dielectric layer, and the protection layer; and electrical contacts, of conductive material, are formed in the vias.

### BACKGROUND

Technical Field

The present disclosure relates to a process for manufacturing integrated electronic devices, in particular CMOS devices using a borderless contact technique.

Description of the Related Art

As is known, in the manufacture of electronic components, in particular CMOS (complementary metal-oxide semiconductor) devices of very small dimensions, such as devices with a gate width of less than 0.18 μm, the borderless contact technique is frequently used. This technique includes depositing a protection layer (which acts also as etch stop), typically of silicon nitride, over operative regions and diffusing the device, prior to depositing a pre-metal dielectric layer (for example, of USG—Undoped Silicon Glass—and BPSG, Boron Phosphorus Silicon Glass), which is planarized. The contacts through the insulating layer are thus obtained by forming through openings in the dielectric layer and in the protection layer, and then depositing an interconnection conductive layer to form conductive through vias. In particular, the through openings are formed by etching, in sequence and selectively, first the dielectric layer, the etch stopping automatically on the protection layer, and then the protection layer, using a photoresist mask (see, for example, U.S. Pat. No. 6,890,815).

Although widely used, the process described is not always optimal. In fact, if the integrated device is not planar, but has projecting or recessed structures and regions, the surface of the substrate has non-negligible level differences, and thus the dielectric layer has thicknesses that are significantly different in the various areas; namely, it is thinner in the projecting areas and thicker in the recessed areas of the substrate.

In some cases, the thickness difference of the dielectric layer may even be considerable, from 200 nm up to even 2 μm.

It follows that etching thick areas of the dielectric takes more time than thin areas. Thus, in order to ensure complete removal of the dielectric layer in the thick areas, etching of the dielectric is continued in the thin areas even after complete local removal. In these areas, if the existing level difference is large, for example, greater than 300 nm, notwithstanding the etching selectivity of the dielectric with respect to the nitride, the protection layer may get damaged.

This damage is disadvantageous in so far as, in these areas, during subsequent etching of the protection layer for completing the openings for forming the contacts, an undesirable over-etching of the underlying regions may occur, which leads to a degradation of the electrical characteristics of the final device, for example short-circuiting of various regions of the component due to an excessive etching in the field oxide.

The above problem afflicts in particular More-than-Moore devices, characterized by a gate width smaller than 0.18 μm, where the three-dimensionality of the structure is at times exploited in order to reduce the dimensions as much as possible.

In general, the discussed problem may afflict also other devices which, due to the lack of planarity of the structure underlying the pre-metal dielectric layer, have dielectric layers of different thicknesses.

In order to solve this problem, it is known to increase the thickness of the protection layer by a value such that it is not significantly removed during etching of the dielectric layer, not even in the areas where the latter is thinner. However, the increase of the thickness of the protection layer may be disadvantageous and is undesirable in so far as the thickness of this layer affects the electrical characteristics of the device. In fact, the thickness of the nitride protection layer determines a stress on the gate region of MOS transistors, affecting the electrical characteristics thereof. On the other hand, a modification of the electrical components in order to limit this impact would not always be possible and in any case would be costly.

### BRIEF SUMMARY

One or more embodiments of the present disclosure provides a manufacturing process that may overcome one or more of the drawbacks mentioned above.

According to the present disclosure, there are provided a process for manufacturing integrated electronic devices and a microintegrated electronic device thus obtained

According to one embodiment, in the devices where the contacts have different levels, the dielectric layer is divided in two parts: a first (bottom) layer above the protection layer, which is not leveled, and a second (top) layer that is leveled so as to have a plane surface. An intermediate layer, of a different material and with a different etching selectivity with respect to the first and to the second dielectric layers (which may be the same as each other) is inserted between the first and second dielectric layers. The intermediate layer, for example of silicon nitride, has a thickness correlated to the level differences on the substrate.

The etching process for defining the contacts has various steps. Initially, the second dielectric layer is etched in a selective way with respect to the material of the intermediate layer. The etch terminates automatically on the intermediate layer. A possible over-etching of the latter due to the difference of thickness does not create problems, since possible damage thereto has no effect on the finished device. Then etching of the intermediate layer, etching of the first dielectric layer, and etching of the protection layer follow. Etching of these bottom layers may thus be performed without any problems, since they have a uniform thickness.

In this way, the thickness of the intermediate layer enables compensation of the various theoretical etching times due to the different thicknesses of the planarized dielectric layer (second dielectric layer). Subsequent etching of the intermediate layer, of the first dielectric layer and of the protection layer may be carried out on a uniform thickness, thus without any risk of over-etching.

### BRIEF DESCRIPTION OF THE SEVERAL VIEWS OF THE DRAWINGS

For a better understanding of the present disclosure a preferred embodiment thereof is now described, purely by way of non-limiting example, with reference to the attached drawings, wherein:

FIGS. 1-5 show cross-sections through a wafer in successive manufacturing steps of an integrated electronic device.

### DETAILED DESCRIPTION

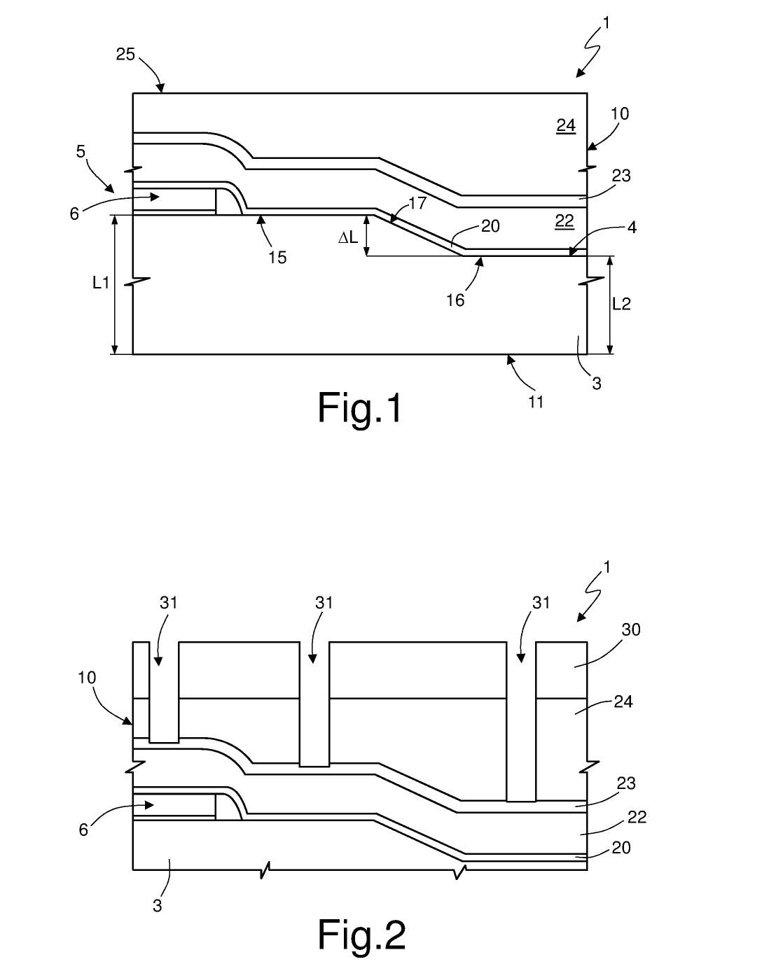

FIG. 1 shows a wafer 1 of semiconductor material integrating an electronic component 5, here a CMOS transistor having an insulated-gate region 6 that uses a borderless contact solution. In the figure, the various regions are not drawn to scale.

The wafer 1 comprises a substrate 3, for example of silicon, which is possibly provided with silicide portions (not shown) and has a non-planar top surface 4. A pre-metal insulation structure 10 extends over the substrate 3.

The substrate 3 accommodates operative regions (not shown), for example implanted and/or diffused, as well as possibly insulation regions (not shown either), which form, together with the insulated-gate region 6, the CMOS transistor 5.

As mentioned, the top surface 4 of the substrate 3 is not planar and has areas at different levels. In detail, in the example shown, the top surface 4 comprises a first portion 15 that extends underneath the insulated-gate region 6 at a first level L1 (for example, measured with respect to a bottom surface 11 of the substrate 3). A second portion 16 of the top surface 4 of the substrate 3 is arranged alongside the first surface portion 15, to which it is joined via radiusing portions 17, and is arranged at a second level L2, lower than the first level L1.

It follows that, between the first level L1 and the second level L2 a level difference ΔL exists, typically between 200 nm and 2 μm, for example 300 nm.

A further level difference (from the pre-metal insulation structure 10, as has been seen) is formed by the top surface of the insulated-gate region 6. This level difference, which in planar structures is negligible, since in general it is less than 250 nm, here adds to the level difference ΔL, contributing to increasing the vertical distance between the contact point at a minimum distance from the top surface of the pre-metal insulation structure 10 and the contact point at a maximum distance (here, the second portion 16 of the top surface 6 of the substrate 3).

The pre-metal insulation structure 10 comprises a stack of layers directly formed on the surface 4, including a protection layer 20, a first insulation layer 22, an intermediate layer 23, and a second insulation layer 24.

The protection layer 20 is deposited in a conformal way on the surface 4 and thus follows the level differences. It is typically of silicon nitride, for example deposited using a LPCVD (Low-Pressure Chemical Vapour Deposition) technique, for an approximately uniform thickness typically of less than 100 nm, for example 20 nm.

The first insulation layer 22 is typically silicon oxide, for example USG (Undoped Silicon Glass) or BPSG (Boron-Phosphorus Silicon Glass) deposited using the LPCVD technique or the APCVD (Atmospheric-Pressure Chemical Vapour Deposition) technique. Also the first insulation layer 22 has an approximately uniform thickness, and its thickness may be chosen with an ample degree of freedom; for example, it may be between 200 and 400 nm.

The intermediate layer 23 is typically silicon nitride or some other material that may be selectively etched with respect to the material of the first insulation layer 22; for example, it may be oxynitride. The intermediate layer 23 is for example deposited using the LPCVD technique, and has an approximately uniform thickness, designed to act as an etch stop, as explained in detail hereinafter. For instance, the thickness of the intermediate layer 23 may be between 10 and 400 nm, in particular between 20 and 100 nm.

The second insulation layer 24 is typically USG or BPSG, deposited using the LPCVD technique or the APCVD technique. After this layer has been deposited, it is planarized, for example via CMP (Chemical Mechanical Polishing) so that its top surface 25 is substantially planar and parallel to the bottom surface 11 of the substrate 3. For instance, after planarization, the second insulation layer 24 may have a minimum thickness, over the first surface portion 15, between 100 and 800 nm.

A mask 30, for example a resist mask (FIG. 2) is lithographically formed on the structure of FIG. 1. The mask 30 covers the top surface 25 of the pre-metal insulation structure 10 and has openings 31, where conductive vias for the contacts are to be provided. A first plasma etch is then carried out, for example using BCl₃, leading to selective removal of the portions of the second insulation layer 24 underneath the openings 31.

As shown in FIG. 2, even though the above etch is very selective with respect to the material of the intermediate layer 23, the presence of the level difference ΔL may cause over-etching of the latter layer, in particular above the first surface portion 15, where the second insulation layer 24 is thinner. The thickness of the intermediate layer 23 is determined, however, on the basis of the estimated over-etching so as not to be completely removed.

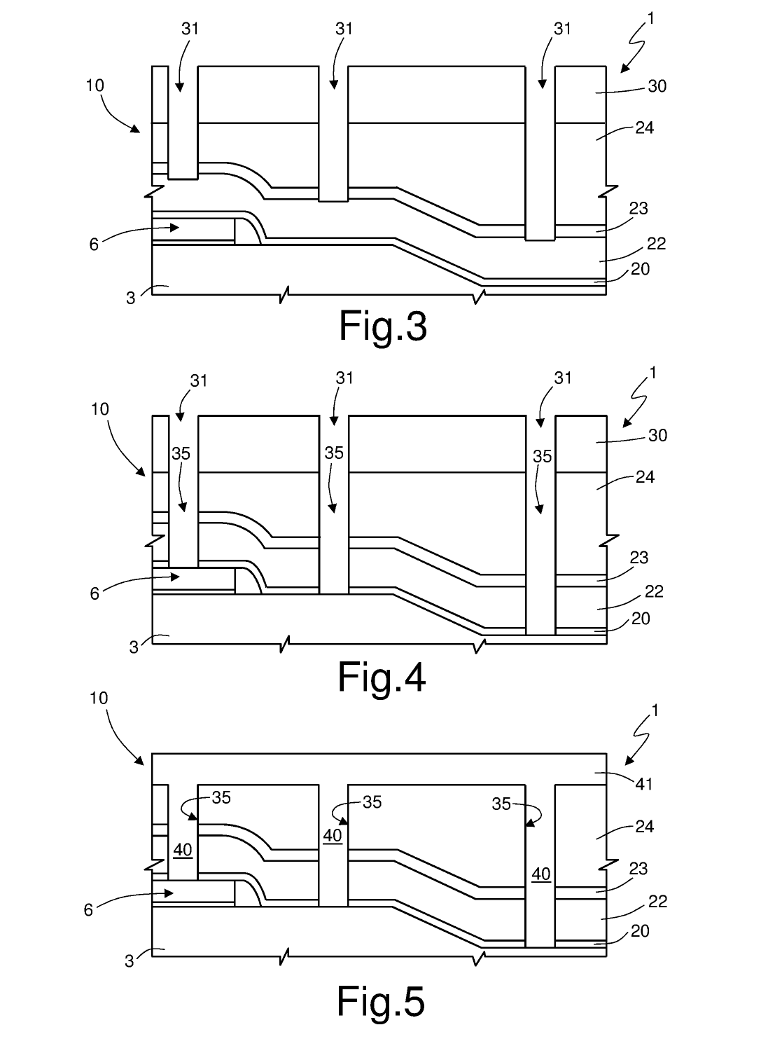

In reference to FIG. 3, while keeping the mask 30 in place, a second plasma etch of the intermediate layer 23 is carried out. This etch completely removes the portions of the intermediate layer 23 underneath the openings 31, stopping on the first dielectric layer 22, because of the selectivity of the etch with respect to the material of the first dielectric layer 22 and also because the second etch removes an approximately uniform thickness of the material of the intermediate layer 23 in all the points.

A third plasma etch is carried out, for example similar to the first etch, for removing the first dielectric layer 22 underneath the openings 31, and stops on the protection layer 20. Also the third etch is made on a substantially uniform thickness, equal to that of the first dielectric layer 22, and thus does not has any criticality.

In reference to FIG. 4, a fourth plasma etch is carried out, for example similar to the second etch, for removing the protection layer 20. Also the fourth etch is made on a substantially uniform thickness, equal to that of the protection layer 20, and thus does not have criticality. In this way, formation of through openings 35 through the structure of insulation 10 is completed.

As shown in FIG. 5, the contacts are made. To this end, in a known way, metal material, for example tungsten, is deposited within the through openings 35 for filling them to form conductive through vias or metal contact regions 40. On the insulating structure 10, a metal layer is deposited and patterned, for example an aluminum or copper layer. The metal contact regions 40 or conductive through vias in the openings 35 and the metallization lines 41 are thus obtained. If the process so envisages, other metals are formed in a per se known manner.

The process and the device thus obtained, as described, have many advantages.

Forming the insulating layer via two dielectric layers 22, 24, separated by a selectively etchable layer, prevents any damage to the borderless protection layer above the substrate. This result is obtained without forgoing the borderless process and without having to adapt the thickness of the borderless protection layer, in particular without increasing it, and thus the process does not specify any design modifications to adapt the geometrical or electrical parameters of the various regions and components of the device, since the thickness of the intermediate layer does not have any effect on them.

The thickness of the first and second dielectric layers 22, 24 are not critical, and the intermediate layer 23 may be arranged at any distance from the protection layer 20 according to the process used and without any particular constraints for the designer.

Finally, it is clear that modifications and variations may be made to the process and to the device described and illustrated herein, without thereby departing from the scope of the present disclosure. For instance, the intermediate layer may be made of a different material, for example oxynitride or some other material having the desired characteristics of selectivity to etching.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A process for manufacturing an integrated electronic device, the process comprising:
forming a protection layer of a first material on a body having a non-planar surface;
forming a first dielectric layer of a second material on the protection layer, the second material being selectively etchable with respect to the first material;
forming an intermediate layer of a third material on the first dielectric layer, the third material being selectively etchable with respect to the second material;
forming a second dielectric layer of a fourth material on the intermediate layer, the fourth material being selectively etchable with respect to the third material;
forming through openings in the second dielectric layer, the intermediate layer, the first dielectric layer, and the protection layer; and
forming conductive vias by depositing conductive material in the through openings.

2. The process according to claim 1, wherein the integrated electronic device is a MOS transistor.

3. The process according to claim 1, wherein the first and third materials are one of silicon nitride and oxynitride, and the second and fourth materials are silicon oxide.

4. The process according to claim 1, wherein the protection layer is a borderless contact protection layer.

5. The process according to claim 4, wherein the intermediate layer has a thickness between 10 and 400 nm.

6. The process according to claim 5, wherein the intermediate layer has a thickness between 20 and 100 nm.

7. The process according to claim 1, wherein forming through openings comprises:
providing a contact mask having openings;
selectively removing the second dielectric layer exposing the intermediate layer;
selectively removing the intermediate layer exposing the first dielectric layer; and
selectively removing the first dielectric layer exposing the body.

8. The process according to claim 1, further comprising forming contacts, wherein forming comprises depositing metal material in the through openings.

9. The process according to claim 1, further comprising planarizing the second dielectric layer before forming the through openings.

10. An integrated electronic device, comprising:
a body having a non-planar surface;
a protection layer of a first material on the body;
a first dielectric layer of a second material on the protection layer, the second material being selectively etchable with respect to the first material;
an intermediate layer of a third material on the first dielectric layer, the third material being selectively etchable with respect to the second material;
a second dielectric layer of a fourth material on the intermediate layer, the fourth material being selectively etchable with respect to the third material; and
conductive through vias extending through the second dielectric layer, the intermediate layer, the first dielectric layer, and the protection layer.

11. The device according to claim 10, wherein the integrated electronic device is a MOS transistor.

12. The device according to claim 10, wherein the first and third materials are one of silicon nitride and oxynitride, and wherein the second and fourth materials are silicon oxide.

13. The device according to claim 10, wherein the protection layer is a borderless contact protection layer.

14. The device according to claim 10, wherein the protection layer, the first dielectric layer, and the intermediate layer have uniform thicknesses, and the second dielectric layer has a planar upper surface.

15. The device according to claim 10, wherein the intermediate layer has a thickness between 10 and 400 nm.

16. The device according to claim 15, wherein the intermediate layer has a thickness between 20 and 100 nm.

17. An integrated electronic device, comprising:
a substrate having a non-planar surface;
a transistor on the non-planar surface;
a protection layer of a first material over the non-planar surface and at least a portion of the transistor;
a first dielectric layer of a second material over the protection layer, the second material being selectively etchable with respect to the first material;
an intermediate layer of a third material over the first dielectric layer, the third material being selectively etchable with respect to the second material;
a second dielectric layer of a fourth material over the intermediate layer, the fourth material being selectively etchable with respect to the third material; and
conductive through vias extending through the second dielectric layer, the intermediate layer, the first dielectric layer, and the protection layer.

18. The device according to claim 17, wherein the first and third materials are one of silicon nitride and oxynitride, and wherein the second and fourth materials are silicon oxide.

19. The device according to claim 17, wherein the intermediate layer has a thickness between 20 and 100 nm.

20. The device according to claim 17, wherein the protection layer, the first dielectric layer, and the intermediate layer are conformal and have non-planar surfaces, and the second dielectric layer has a planar upper surface.
